(19) United States
(12) Patent Application Publication
(10) Pub. No.: US 2005/0236171 A1
(43) Pub. Date: Oct. 27, 2005

(54) Shield frame for a radio frequency shielding assembly

(76) Inventor: Jorge L. Garcia, Plantation, FL (US)

Correspondence Address: BARBARA R. DOUTRE;Motorola, Inc., Law Department, 8000 West Sunrise Boulevard, Fort Lauderdale, FL, 33322, US

(21) Appl. No.: 10/830,947

(22) Filed: Apr. 23, 2004

(51) Int. Cl. H05K 9/00

(52) U.S. Cl. 174/35 GC; 174/35 R

(57) ABSTRACT

A shield frame (100) is provided that allows for a narrow width shield track to be used in a radio frequency (RF) shielding apparatus (300, 500). The shield frame (100) is formed of a sheet metal frame (102) overmolded with a conductive elastomer (104) to provide compliance in a z-axis (114) direction and stiffness in x-axis and y-axis directions (116, 118). The shield frame (100) is sandwiched between two substrates (120, 122) of a shielding assembly, one substrate having electrical components in need of isolation (326) and the other providing a ground plane (322, 522). The shield frame (100) is compartmentalized (112) to align with the areas in need of isolation.

### TECHNICAL FIELD

This invention relates in general to radio frequency (RF) shields and more particularly to RF shielding assemblies for electronic devices having size constraints.

### BACKGROUND

As electronic devices continue to shrink, space on circuit boards becomes a critical consideration. Shielding takes up a significant portion of board space. Furthermore, the need for complete perimeter ground contact is an electrical necessity to provide sub-circuit isolation.

Traditional shielding approaches have used sheet metal cans soldered onto a board. The problem with the soldered-can approach is that considerable board space is required, especially when using side by side solder tracks. A process known as pinch trimming can be used to eliminate the small lip around the can prior to the can being soldered to the board. While pinch trimming minimizes the required width of solder tracks significant board space is still required when side by side cans are used.

Several compliant conductive elastomer approaches are available as alternatives to solder cans. Dispensing a bead onto a sheet metal can, metalized plastic or casting is one approach. However, the dispensed bead approach is labor intensive and often requires significant clamping loads. Another approach is to overmold a conductive elastomer directly over a sheet metal can, metalized plastic or casting. The overmolded can approach combines metal or metalized plastic cans with a conductive gasket overmolded directly to the can. The disadvantage to the overmolded can approach is that it is not z-space efficient particularly in stacked board assemblies in which one board is used to complete shielding via a ground plane.

A spacer gasket approach can be used to minimize z in stacked board assemblies where one board is completing the shield via a ground plane. In the spacer gasket approach a plastic gasket is first molded with a desired compartmentalization. Afterwards, a conductive elastomer is overmolded onto the side walls of each of the compartments in the plastic. Unfortunately, the spacer approach requires injection molding tools for both plastic and elastomer and is thus tooling intensive. Furthermore, because the elastomer is molded onto the sides of the plastic walls, large track widths (2mm) are required thus making the spacer gasket approach impractical for miniaturized designs having tight board space requirements.

Accordingly, there is a need for an improved shield assembly. The ability to use a narrow width shield track would be particularly beneficial to communications products having tight space requirements.

### BRIEF DESCRIPTION OF THE DRAWINGS

The features of the present invention, which are believed to be novel, are set forth with particularity in the appended claims. The invention, together with further objects and advantages thereof, may best be understood by reference to the following description, taken in conjunction with the accompanying drawings, in the several figures of which like reference numerals identify like elements, and in which:

FIG. 1 is a shield frame in accordance with the present invention;

FIG. 2 is the sheet metal frame portion of the shield frame of FIG. 1 in accordance with the present invention;

FIG. 3 is an exploded view of the shield frame being used in an assembly of a communication device in accordance with a first embodiment of the invention;

FIG. 4 is assembled view of FIG. 3 in accordance with the first embodiment of the invention;

FIG. 5 is an exploded view of the shield frame being used in an assembly of a communication device in accordance with a second embodiment of the invention; and

FIG. 6 is an assembled view of FIG. 5 in accordance with the second embodiment of the invention.

### DETAILED DESCRIPTION OF THE PREFERRED EMBODIMENT

While the specification concludes with claims defining the features of the invention that are regarded as novel, it is believed that the invention will be better understood from a consideration of the following description in conjunction with the drawing figures, in which like reference numerals are carried forward.

In accordance with the present invention, there is disclosed herein a shield frame for use in a radio frequency (RF) shielding apparatus. The shield frame of the present invention comprises a sheet metal frame overmolded with a conductive elastomer to provide compliance in a z-axis direction and stiffness in x-axis and y-axis directions. The compliant nature of the frame provides optimum ground contact with a reduced shield track area and minimum clamping load.

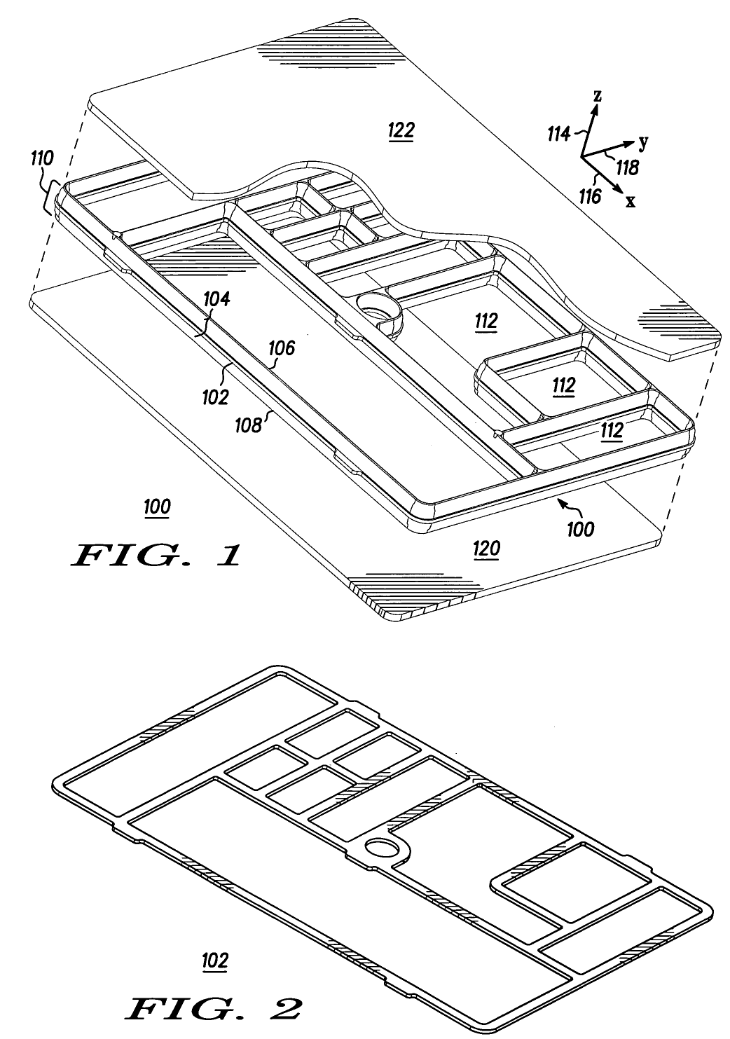

FIG. 1 is a shield frame 100 in accordance with the present invention. The shield frame 100 is formed of a sheet metal frame 102, also shown separately in FIG. 2, having a conductive elastomer 104 overmolded thereon. The elastomer overmold 104 forms a first portion 106 of a wall 110 above the sheet metal frame 102 and a second portion 108 of the wall below the sheet metal frame. The shield frame 100 is compartmentalized 112 to provide various areas of isolation. A variety of known techniques can be used to overmold the sheet metal frame 102 such that the material forms the upper and lower portions 106, 108. For example, holes within the sheet metal frame 102 can be used to facilitate adhesion of the overmold to the frame.

The first and second portions 106, 108 of the wall 110 become compressibly coupled between first and second conductive substrates 120, 122 of a radio frequency (RF) shielding assembly. In accordance with the present invention, the wall 110 compressibly couples in the z-axis direction 114 but has stiffness in x-axis and y-axis directions 116, 118.

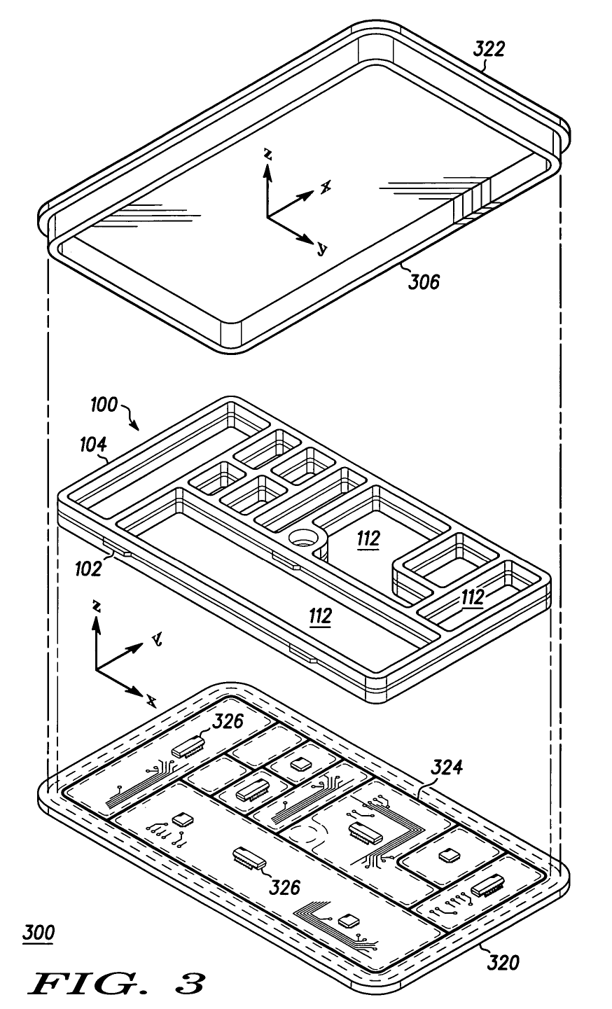

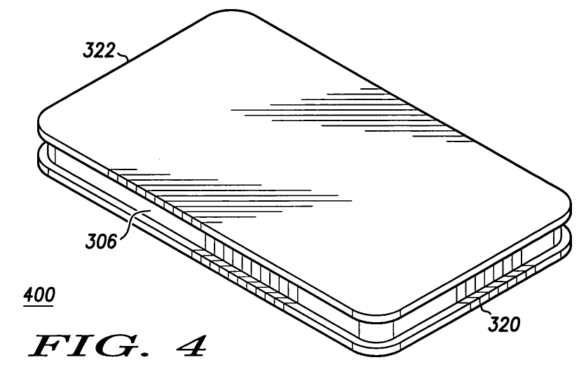

FIG. 3 is an exploded view of the shield frame 100 being used in an assembly of a communication device in accordance with a first embodiment 300 of the invention. In this first embodiment, the first substrate is a printed circuit board 320 and the second substrate is a metal casting 322 or metalized plastic. As in FIG. 1, the sheet metal frame is 102 overmolded with the conductive elastomer 104 and compartmentalized 112 to provide areas of isolation. The printed circuit board 320 includes a ground runner 324 and electrical components 326 disposed thereon in need of isolation. The ground runner 324 of printed circuit board 320 aligns with the compartments 112 of shield frame 100. The shield frame 100 of the present invention gets compressibly and electrically coupled between the ground runner 324 of the printed circuit board 320 and the metal casting 322, the casting thus forming the ground plane for the assembly. A compression stop device 306 is used to limit compression between printed circuit board 320 and the metal casting 322. In this first embodiment, the compression stop device 306 is integrally formed on the casting as a ledge for receiving the shield frame 100.

FIG. 4 is an assembled view 400 of FIG. 3 in accordance with the first embodiment of the invention. The circuit board 320 and metal casting 322 are compressibly coupled together with the integral ledge of the casting providing the compression stop 306 therebetween. The overmolded elastomer 104 compresses in the z-axis direction along the sides of the ledge but retains stiffness in the x-axis and y-axis directions due to the stiffness of the sheet metal frame 102.

Assembly 300/400 provides RF isolation to the electronic components 326 within the open compartments 112 through the metal casting, compression stop 306 and ground runner 324. The shield frame 100 of the present invention can be formed of much thinner walls 110 than the walls of a traditional side by side shield cans. Thus, a thinner ground runner 324 can be used on the printed circuit board 320 as a shield track than was possible in past assemblies. For example, a 1.2 mm shield track can be used instead of the 2mm track discussed previously.

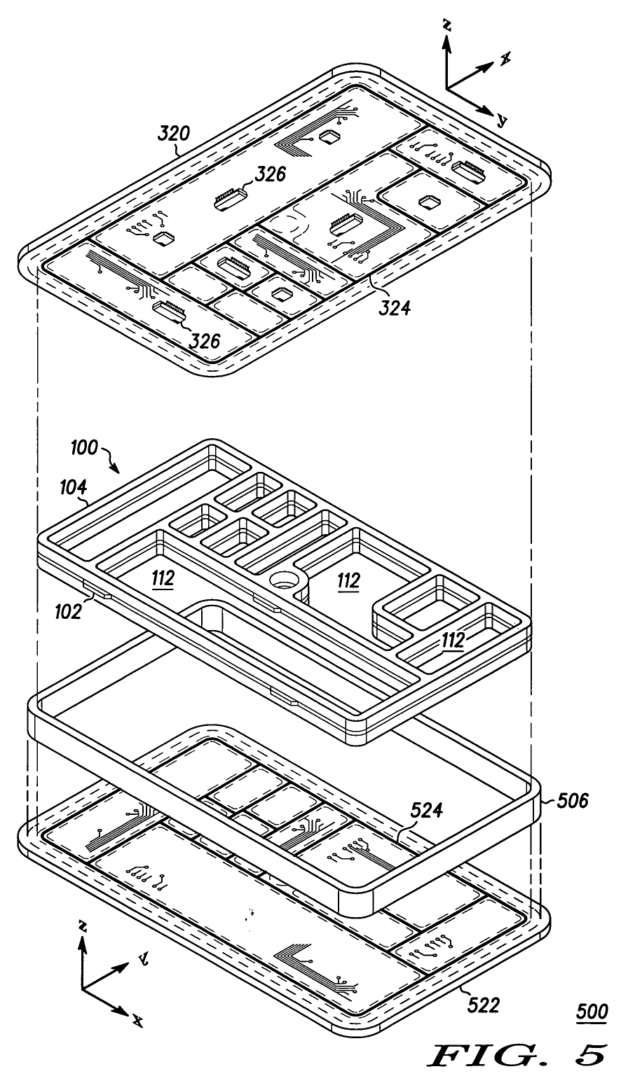

FIG. 5 is an exploded view of the shield frame 100 being used in an assembly of a communication device in accordance with a second embodiment 500 of the invention. In this second embodiment, the first and second substrates are both printed circuit boards 320, 522. The first circuit board 320, as in FIG. 3, comprises the ground runner 324 and electrical components 326 disposed thereon. The second printed circuit board 522 provides a ground plane and exposed ground runner 524. Ground runner 524 of printed circuit 522 aligns with compartments 112 of shield frame 100. Likewise, printed circuit board 320's ground runner aligns with compartments 112 of shield frame 100. When using the two board approach, a separate compression stop device 506, such as a plastic piece part, is used to limit compression the two boards 320, 522. The shield frame 100 is retained within the separate compression stop device 506. In accordance with the second embodiment, the shield frame 100 couples the ground runner 324 of the first board 320 to the ground plane of second board 522 through ground runner 524 and thus provides RF isolation to the electronic components 326 within the compartments 112.

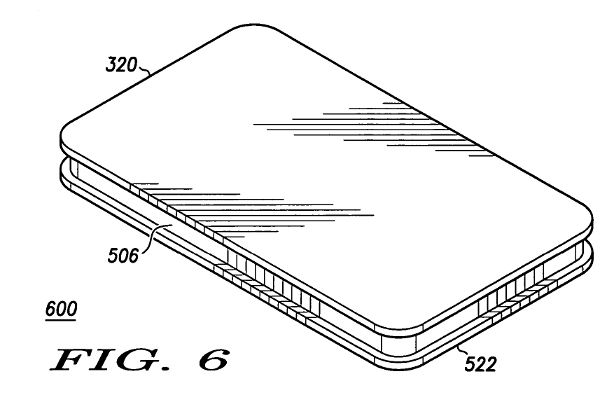

FIG. 6 is an assembled view 600 of FIG. 5 in accordance with the second embodiment of the invention. The two boards 320, 522 are compressibly and electrically together with the separate compression stop 506 therebetween. In accordance with the present invention, the overmolded elastomer 104 compresses in the z-axis direction between the two boards but retains stiffness in the x-axis and y-axis directions due to the stiffness of the sheet metal frame 102.

Assembly 500/600 provides RF isolation to the electronic components 326 within the open compartments 112 through the printed circuit board 522, compression stop device 506 and ground runner 324. Again, the shield frame 100 allows for a thinner ground runner 324 to be used on the printed circuit board 320 thereby facilitating tight space constraints.

There are advantages to using the first embodiment shielding assembly approach having the metal casting in that a plurality of circuit boards each having different areas in need of isolation can be accommodated with a single metal casting. By providing a plurality of overmolded sheet metal frames each having different areas of compartmentalization that align with the different areas in need of isolation, a single metal casting can be used to interchangeably couple each of the plurality of overmolded sheet metal frames to each of the plurality of circuit boards with which each aligns. Each of the plurality of overmolded sheet metal frames can be interchanged within the integrally formed ledge of the metal casting. Thus, the use of the overmolded sheet metal frame of the present invention allows for one single metal casting to be used in conjunction with different circuit board layouts. By not having to compartmentalize the metal casting, the same metal casting can be used for multiple assemblies thereby reducing cost.

Accordingly, there has been provided a shield frame 100 that provides for an improved shield assembly. The shield frame formed in accordance with the present invention is much thinner than the walls of a traditional side by side shield cans and thus a thinner ground runner can be used on the substrate. The compartmentalization of the shield frame eliminates the need for separate solder cans further facilitating thin runners and miniaturization. The metal casting or metalized plastic need not be tooled for separate compartments thereby reducing tooling costs. The shield frame compartments can be formed for a variety of circuit layouts while still using the same casting which provides significant design flexibility.

While the preferred embodiments of the invention have been illustrated and described, it will be clear that the invention is not so limited. Numerous modifications, changes, variations, substitutions and equivalents will occur to those skilled in the art without departing from the spirit and scope of the present invention as defined by the appended claims.

1. A shield frame for use in a radio frequency (RF) shielding apparatus, the shield frame comprising a compartmentalized sheet metal frame overmolded with a conductive elastomer to provide compliance in a z-axis direction and stiffness in x-axis and y-axis directions.

2. A shield frame for use in a radio frequency (RF) shielding apparatus, comprising:
a comparmentalized sheet metal frame;
a conductive elastomer overmolded to the compartmentalized sheet metal frame so as to form a first portion of a wall above the compartmentalized sheet metal frame and a second portion of the wall below the compartmentalized sheet metal frame, the first and second portions of the wall for compressibly coupling between first and second conductive substrates.

3. The shield frame of claim 2, wherein the wall compressibly couples in a z-axis direction but has stiffness in x-axis and y-axis directions.

4. The shield frame of claim 2, wherein the first substrate comprises a printed circuit board and the second substrate comprises a metal casting.

5. The shield frame of claim 2, wherein the first substrate comprises a printed circuit board and the second substrate comprises a printed circuit board.

6. The shield frame of claim 2, wherein the first substrate comprises a printed circuit board and the second substrate comprises metalized plastic.

7. A shielding assembly, comprising:
first and second substrates, the first substrate providing an electrical ground runner and the second substrate providing a ground plane;
a sheet metal frame having open compartmentalized areas;
a conductive elastomer overmolded to the sheet metal frame so as to form upper and lower portions of a wall, the conductive elastomer being compressibly coupled between the first and second substrates such that the upper portion of the wall electrically couples to the ground runner and the lower portion of the wall electrically couples to the ground plane.

8. The shielding assembly of claim 7, wherein the second substrate comprises a metal casting.

9. The shielding assembly of claim 8, wherein the metal casting further includes an integrally formed ledge within which to receive the lower portion of the wall and to provide a compression stop to the first substrate.

10. The shielding assembly of claim 7, wherein the second substrate comprises a printed circuit board having a ground plane.

11. The shielding assembly of claim 10, further comprising a compression stop device to limit the amount of compression between the first and second substrates.

12. A communication device, comprising:
a first substrate having electronic components disposed thereon and ground runners surrounding various groups of the electronic components;
a second substrate providing a ground plane;
a sheet metal frame overmolded with a conductive elastomer, the sheet metal frame compartmentalizing the various groups of electronic components, the sheet metal frame being compressibly and electrically coupled between the ground runners of the first substrate and the ground plane of the second substrate.

13. The communication device of claim 12, further comprising a compression stop device for limiting compression between the two substrates.

14. The communication device of claim 13, wherein the first and second substrates are printed circuit boards.

15. The communication device of claim 13, wherein the first substrate is a printed circuit board and the second substrate is a metal casting.

16. The communication device of claim 14, wherein the compression stop device is a separate piece part.

17. The communication device of claim 15, wherein the compression stop device is integrally formed on the casting.

18. The communication device of claim 12, wherein the sheet metal frame overmolded with a conductive elastomer provides compliance in a z-axis direction and stiffness in x-axis and y-axis directions.

19. A shielding assembly, comprising:
a plurality of circuit boards each having different areas in need of isolation;
a plurality of overmolded sheet metal frames each having different areas of compartmentalization that align with the different areas in need of isolation; and
a single metal casting for interchangeably coupling each of the plurality of overmolded sheet metal frames to each of the plurality of circuit boards with which each aligns.

20. The shielding assembly of claim 19, wherein each of the plurality of overmolded sheet metal frames provides compliance in a z-axis direction and stiffness in x-axis and y-axis directions.

21. The shielding assembly of claim 20, wherein the metal casting includes an integrally formed ledge within which each of the plurality of overmolded sheet metal frames is interchanged.
